(19) United States
(12) Patent Application Publication
(10) Pub. No.: US 2011/0076032 A1
(43) Pub. Date: Mar. 31, 2011

(54) HIGH-SPEED SPECTRAL GAIN OFFSET OPTICAL TRANSMITTER

(75) Inventors: Ashish K. Verma, San Jose, CA (US); Tsurugi Sudo, San Jose, CA (US)

(73) Assignee: FINISAR CORPORATION, Sunnyvale, CA (US)

(21) Appl. No.: 12/569,540

(22) Filed: Sep. 29, 2009

(51) Int. Cl. H04B 10/04; H01S 5/12

(52) U.S. Cl. 398/186; 372/45.01; 372/96

(57) ABSTRACT

In one example, a DFB laser includes a substrate, an active region, and a grating. The active region is formed above the substrate and is designed to emit light having a gain peak wavelength. The grating is formed above the active region and is designed to provide optical feedback for light having a lasing peak wavelength. The gain peak wavelength is longer than the lasing peak wavelength and a difference between the gain peak wavelength and the lasing peak wavelength at room temperature is between 10 nm and 50 nm.

### BACKGROUND

1. Field of the Invention

The present invention generally relates to optical transmitters. In particular, some example embodiments relate to a directly modulated optical transmitter optimized for operation at 25 gigabits per second (“G”).

2. Related Technology

Semiconductor lasers are currently used in a variety of technologies and applications, including communications networks. One type of semiconductor laser is the distributed feedback (“DFB”) laser. The DFB laser produces a stream of coherent, monochromatic light by stimulating photon emission from a solid state material. DFB lasers are commonly used in optical transmitters, which are responsible for modulating electrical signals into optical signals for transmission via an optical communication network.

Generally, a DFB laser includes a positively or negatively doped bottom layer or substrate, and a top layer that is oppositely doped with respect to the bottom layer. An active region, bounded by confinement regions, is included at the junction of the two layers. These structures together form the laser body. A coherent stream of light that is produced in the active region of the DFB laser is emitted through either longitudinal end, or facet, of the laser body. One facet is typically coated with a high reflective material that redirects photons produced in the active region toward the other facet to maximize the emission of coherent light from that facet end. A grating is included in either the top or bottom layer to assist in producing a coherent photon beam. DFB lasers are typically known as single mode devices as they produce light signals at one of several distinct wavelengths, such as 1,310 nanometers (“nm”) or 1,550 nm. Such light signals are appropriate for use in transmitting information over great distances via an optical communications network.

The subject matter claimed herein is not limited to embodiments that solve any disadvantages or that operate only in environments such as those described above. Rather, this background is only provided to illustrate one exemplary technology area where some embodiments described herein may be practiced

### BRIEF SUMMARY OF SOME EXAMPLE EMBODIMENTS

In general, example embodiments relate to optical transmitters optimized for operation at directly modulated bitrates up to 25 G or higher.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

In one example embodiment, a DFB laser includes a substrate, an active region, and a grating. The active region is formed above the substrate and is designed to emit light having a gain peak wavelength. The grating is formed above the active region and is designed to provide optical feedback for light having a lasing peak wavelength. The gain peak wavelength is longer than the lasing peak wavelength and a difference between the gain peak wavelength and the lasing peak wavelength at room temperature is between 10 nm and 50 nm.

In another example embodiment, a method of at least partially optimizing output performance of a laser includes selecting a length of an active region of the laser to be 180 micrometers (“μm”) or less. The method also includes selecting a spectral gain offset of the laser to be negative 10 nm or less. The method also includes selecting a thickness of a grating of the laser to be 30 nm or more.

In yet another example embodiment, an optoelectronic device includes a driver and an optical transmitter. The driver is configured to generate a modulation signal from an electrical data signal received from a host. The optical transmitter is configured for operation at a data rate substantially equal to 25 G and is operably connected to the driver. Additionally, the optical transmitter is configured to receive the modulation signal and to emit an optical data signal representative of the electrical data signal. The optical transmitter includes a substrate, an active region, and a grating. The active region is formed above the substrate and is designed to produce light having a gain peak wavelength. The active region has a length between 120 μm and 180 μm. The grating is formed above the active region and is designed to provide optical feedback for light having a lasing peak wavelength. The grating has a thickness between 30 nm and 40 nm. The gain peak wavelength is longer than the lasing peak wavelength and a difference between the gain peak wavelength and the lasing peak wavelength at room temperature is between 10 nm and 50 nm.

These and other features of the present invention will become more fully apparent from the following description and appended claims, or may be learned by the practice of the invention as set forth hereinafter.

### BRIEF DESCRIPTION OF THE DRAWINGS

To further clarify the above and other features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates an example optoelectronic device including one or more optical transmitters according to some embodiments;

FIG. 2A is a progressive view of various processing and manufacture stages of an optical transmitter including a DFB laser such as may be employed in the optoelectronic device of FIG. 1;

FIG. 2B is a cross sectional side view of an epitaxial base portion of the DFB laser formed according to the processing and manufacture stages of FIG. 2A;

FIG. 2C illustrates mirror reflectivities R1 and R2 of the DFB laser formed according to the processing and manufacture stages of FIG. 2A; and

FIG. 3 illustrates a flowchart of an example method for at least partially optimizing output performance of an optical transmitter in accordance with examples disclosed herein.

### DETAILED DESCRIPTION

Some embodiments are directed to optical transmitters optimized for high-speed operation. Example embodiments include DFB lasers configured for operation at data rates of up to about 25 G or higher. In some embodiments, one or more design parameters of the DFB lasers are selected to optimize the performance of the DFB lasers. For example, in some embodiments, a length of an active region of the DFB laser is selected to be between 120 and 180 μm. Alternately or additionally, a spectral gain offset of the DFB laser is selected to be between negative 10 nm and negative 50 nm. Alternately or additionally, a thickness of a grating of the DFB laser is selected to be between 30 and 40 nm.

Reference will now be made to the drawings to describe various aspects of exemplary embodiments of the invention. It should be understood that the drawings are diagrammatic and schematic representations of such exemplary embodiments and, accordingly, are not limiting of the scope of the present invention, nor are the drawings necessarily drawn to scale.

### A. Example Operating Environment

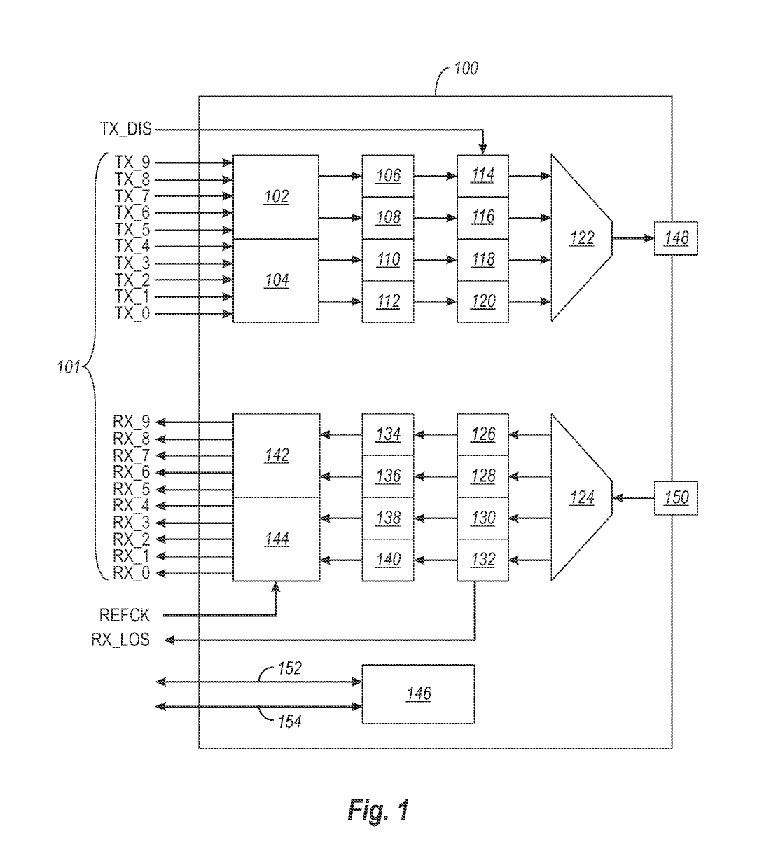

Reference is first made to FIG. 1, which depicts an example optoelectronic device 100 for use in transmitting and receiving optical signals in connection with an external host (not shown) that is operatively connected in some embodiments to a communication network (not shown). While the optoelectronic device 100 will be described in some detail, the optoelectronic device 100 is described by way of illustration only, and not by way of restricting the scope of the invention. For instance, the optoelectronic device 100 may be suitable for optical signal transmission and reception at a variety of per-second data rates, including, but not limited to, 10 G, 25 G, 40 G, 100 G, or higher data rates. Furthermore, the principles of embodiments of the invention can be implemented in optoelectronic devices configured for shortwave or long wave optical transmission and having any form factor such as XFP and CFP, without restriction.

In addition, some of the components included in the optoelectronic device 100 of FIG. 1 are not required to be implemented in all embodiments. For instance, the optoelectronic device 100 can include an optical multiplexer (“MUX”) and/or demultiplexer (“DEMUX”) to implement coarse or dense wavelength division multiplexing (“WDM”), or the optical MUX and/or DEMUX can be omitted when the optoelectronic device 100 implements parallel optics or in phase and quadrature phase (“I and Q”) channels. Similarly, the optoelectronic device 100 can include one or more serializer, deserializer, and/or serializer/deserializer (“SerDes”) integrated circuits (“ICs”) for performing parallel-to-serial and serial-to-parallel electrical signal conversion, and/or such ICs can be omitted and optionally be replaced by one or more clock and data recovery (“CDR”) ICs.

With continued reference to FIG. 1, the optoelectronic device 100 includes an electrical interface 101 configured to be connected to a host (not shown), a plurality of serializers 102, 104, a plurality of modulation drivers 106, 108, 110, 112, a plurality of optical transmitters 114, 116, 118, 120, an optical MUX 122, an optical DEMUX 124, a plurality of optical receivers 126, 128, 130, 132, a plurality of post amplifiers 134, 136, 138, 140, a plurality of deserializers 142, 144, and a microcontroller 146.

In the present example, the electrical interface 101 is configured to support an aggregate data rate substantially equal to 100 G in each direction, the electrical interface 101 implementing a 10×10 G architecture having ten transmit signal lanes TX_0-TX_9 for receiving up to ten outbound 10 G data signals from the host (not shown), and ten receive signal lanes RX_0-RX_9 for providing up to ten incoming 10 G data signals to the host. Alternately, the electrical interface 101 can implement a different architecture than 10×10 G and/or be configured for a different aggregate data rate than 100 G.

Each serializer 102, 104 is operably connected to a different half of the ten transmit signal lanes TX_0-TX_9, allowing each serializer 102, 104 to receive a different half of the outbound data signals from the host device (not shown). The serializers 102, 104 in the embodiment of FIG. 1 each provide a 5:2 parallel-to-serial mapping function to collectively serialize the ten outbound 10 G data signals into four 25 G serial data signals in the present example. In other embodiments there may be more or fewer than two serializers 102, 104 that provide the same or different mapping functions.

Modulation drivers 106, 108, 110, 112 receive the serial data signals generated by the serializers 102, 104 and drive optical transmitters 114, 116, 118, 120 to emit optical data signals representative of the information carried in the corresponding serial data signal. In some embodiments, the optical transmitters 114, 116, 118, 120 are each configured for optical signal transmission at a data rate of 25 G. In other embodiments, the optical transmitters 114, 116, 118, 120 are configured for optical signal transmission at other data rates. The emitted optical data signals are optically multiplexed by optical MUX 122 and transmitted onto an optical fiber 148.

The optoelectronic device 100 is also configured to receive a multiplexed optical data signal from an optical fiber 150, which multiplexed optical data signal is optically demultiplexed by optical DEMUX 124 into a plurality of demultiplexed optical data signals. The demultiplexed optical data signals are converted to electrical serial data signals by optical receivers 126, 128, 130, 132 and amplified by post amplifiers 134, 136, 138, 140.

The deserializers 142, 144 each receive half of the amplified serial data signals and provide a 2:5 serial-to-parallel mapping function to collectively deserialize the four serial data signals into ten inbound 10 G parallel data signals in the present example, which are provided to a host (not shown) via the ten receive signal lanes RX_0-RX_9. In other embodiments there may be more or fewer than two deserializers 142, 144 that provide the same or different mapping functions.

The microcontroller 146 is configured to optimize dynamically varying performance of the optoelectronic device 100 by, for example, adjusting settings on each of the modulation drivers 106, 108, 110, 112 and/or post amplifiers 134, 136, 138, 140. Various interfaces, including firmware I/O interface 152 and/or hardware I/O interface 154, permit the microcontroller 146 to communicate directly with the host (not shown) and/or various components within the optoelectronic device 100.

Having described a specific operating environment with respect to FIG. 1, it will be understood that this specific operating environment is only one of countless architectures in which some embodiments may be employed. For instance, some embodiments can alternately or additionally be employed in optoelectronic devices having a single transmit signal lane and a single optical transmitter, or in optoelectronic devices having more than one transmit signal lane and more than one optical transmitter, as well as in other environments. As previously stated, the principles of embodiments of the present invention are not intended to be limited to any particular environment.

### B. Example Distributed Feedback Laser

A DFB laser is one example of an optical transmitter that can be employed according to some embodiments. For instance, each of the optical transmitters 114, 116, 118, 120 of FIG. 1 may include a DFB laser configured for operating at data rates of about 25 G (referred to herein as a “25 G DFB laser”) in some embodiments. By way of general overview, a DFB laser contains a cavity having an active medium and a distributed reflector that operates in a wavelength range of the laser action. The DFB laser has multiple modes, including both longitudinal and transversal modes, but one of these modes will typically offer better loss characteristics relative to the other modes. This single mode typically defines a single-frequency operation of the DFB laser.

The following description provides various details regarding a 25 G DFB laser configured for light emission at a wavelength of approximately 1310 nm according to some embodiments. However, the embodiments disclosed herein are not limited to 25 G DFB lasers emitting light at approximately 1310 nm. For instance, some embodiments include optical transmitters configured for higher or lower data rates than 25 G and configured for light emission at higher or lower wavelengths than 1310 nm.

Additionally, the following description includes both structural and functional characteristics of a 25 G DFB laser, together with certain details regarding the manufacturing processes used to build the laser. Note, however, that this description is intended to be illustrative only; indeed, lasers and other optical transmitters having structural and/or functional aspects that differ from the present description can also benefit from some or all of the principles disclosed herein. It is also appreciated that additional or alternative layers, layer thicknesses, or structures can be incorporated into the present laser device as will be understood by those of skill in the art. The following discussion is therefore not intended to limit the invention in any way.

1. Stage 1: Base Epitaxial Layers

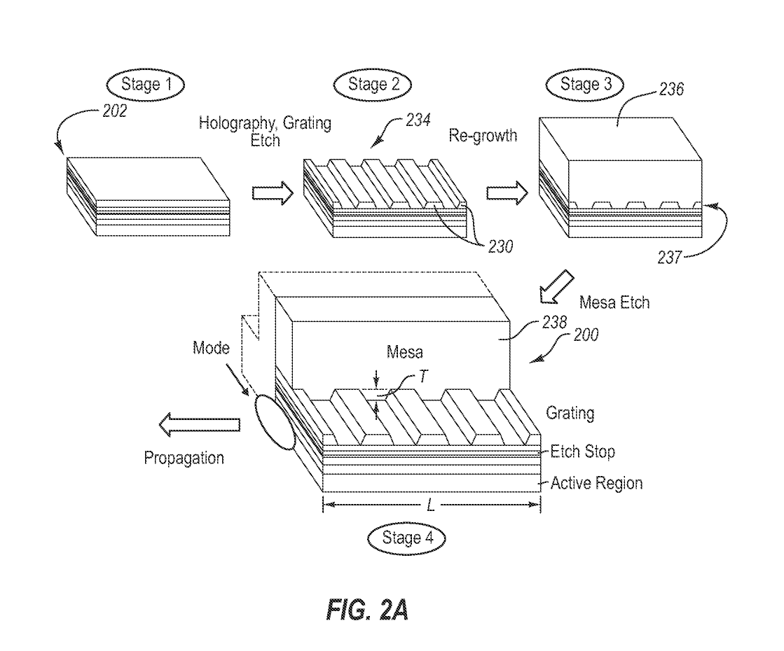

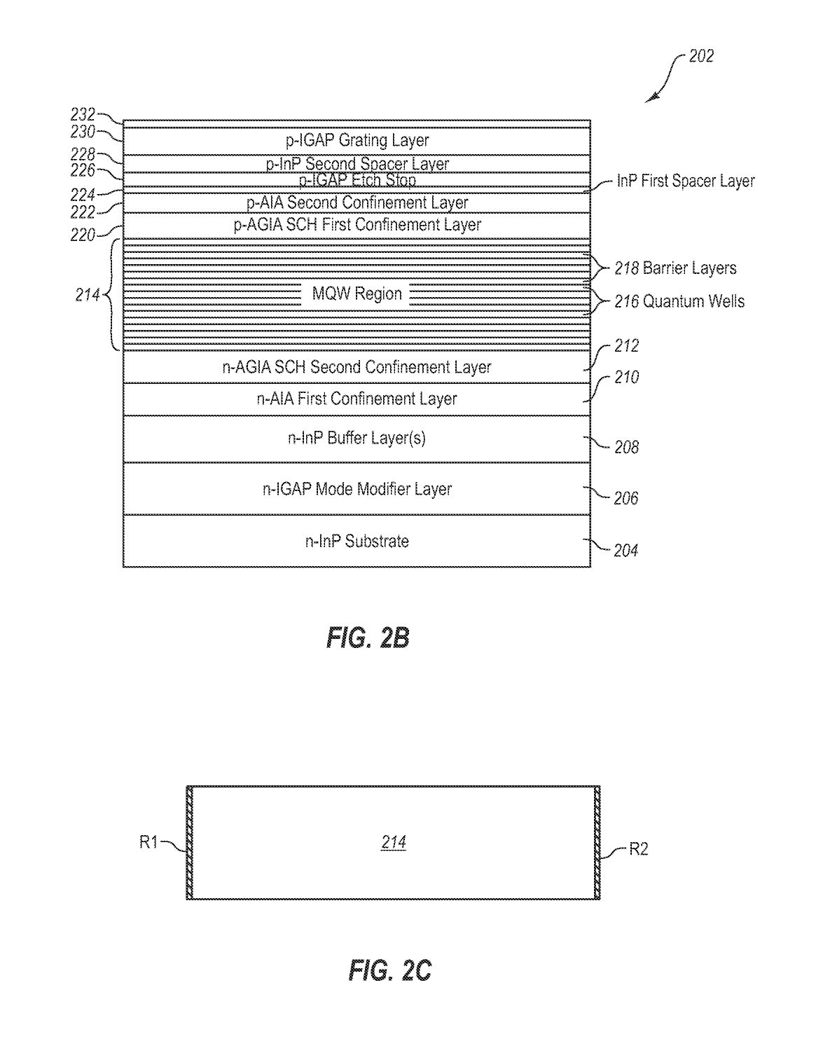

FIGS. 2A-2C illustrate aspects of a DFB laser configured for operation at a data rate of approximately 25 G, the DFB laser being generally designated at 200 (FIG. 2A). At the outset, it will be appreciated in light of the present disclosure that FIGS. 2A-2C are not drawn to scale.

FIG. 2A illustrates a process of forming the DFB laser 200. Various stages of the process of forming the DFB laser 200 are identified in FIG. 2A by respective identifiers, including “stage 1,” “stage 2,” “stage 3” and “stage 4,” which generally correspond to subsections 1, 2, 3 and 4 herein.

The DFB laser 200 is formed from a base epitaxial portion 202. The base epitaxial portion 202 may be formed during stage 1 depicted in FIG. 2A, for example. Details of an example of the base epitaxial portion 202 prior to etching of various layers of the base epitaxial portion 112 during stage 2 are provided in FIG. 2B.

In the example illustrated in FIG. 2B, the base epitaxial portion 202 is grown on an n-type Indium Phosphide (“n-InP”) substrate 204.

A mode modifier layer 206 including n-type Indium Gallium Arsenide Phosphide (“n-InGAP”) is grown on top of the n-InP substrate 204 at an approximate thickness of 120 nm. The mode modifier layer 206 functions to reduce the power of second-order transversal modes that propagate within the structure of DFB laser 200. In particular, the mode modifier layer 206 effectively increases the loss associated with these second-order transverse modes and couples the modes away from the gain medium of the DFB laser 200. The suppression of second-order transverse modes allows for wider mesa widths on the DFB laser 200 because the DFB laser 200 is less sensitive to these modes. In other embodiments, the mode modifier layer 206 may have corresponding thickness of more or less than 120 nm.

A buffer layer 208 including n-type InP is grown on top of the mode modifier layer 206. The buffer layer 208 provides a surface on which various n-type layers of the DFB laser 200 are grown.

A first n-confinement layer 210 is grown on the buffer layer 208 and is doped with silicon. A second n-confinement layer 212 is grown on the first confinement layer 210 and is also doped with silicon. Both of first and second n-confinement layers 210, 212 are current confinement layers and effectively maintain electrons and holes within an active region of the DFB laser 200 so that photons are produced. The second n-confinement layer 212 is graded in some embodiments to improve the confinement characteristics of the second n-confinement layer 212.

A multiple quantum well (“MQW”) active region 214 is grown on the second n-confinement layer 212. The active region 214 is designed to have eight quantum wells 216 with corresponding wavelengths of approximately 1325 nm. In other embodiments, the active region 214 has more or less than eight quantum wells 216, including nine to eleven quantum wells 216 in some examples. Alternately or additionally, the quantum wells 216 have corresponding wavelengths of more or less than 1325 nm. Quantum barriers 218 are formed between the quantum wells 216. The barriers 218 have corresponding wavelengths of approximately 1007 nm. In other embodiments, the barriers 218 have corresponding wavelengths of more or less than 1007 nm.

In some embodiments, the depth and width of the quantum wells 216 are designed to produce light having a gain peak wavelength at room temperature (e.g., about 25° C. to 45° C.) of about 1340 nm. Alternately or additionally, the active region 214 is designed to be “strain compensated,” which means that the barriers 218 are designed to have opposing strain characteristics relative to strain characteristics of the quantum wells 216. As a result, the strain generated from the barriers 218 at least partially cancels the strain generated by the quantum wells 218 and reduces the overall strain on the active region 214.

In the present example, the layers 216, 218 of the active region 214 are deliberately doped with zinc (“Zn”) to maintain a low-level p-type doping. The Zn doping is configured to assure that a p-n junction of the DFB laser 200 always occurs in the same place, and is not made variable by unpredictable dopant diffusion processes.

In the illustrated example of FIG. 2B, a first p-confinement layer 220 is grown on the active region 214. A second p-confinement layer 222 is grown on the first p-confinement layer 220. Both of the first and second p-confinement layers 220, 222 are current confinement layers and effectively maintain electrons and holes within the active region 214 so that photons are produced. The first p-confinement layer 220 is graded in some embodiments to improve the confinement characteristics of the first p-confinement layer 220.

A first spacer layer 224 is grown on the second p-confinement layer 222. The first spacer layer 224 is made of InP in some embodiments. The first spacer layer 224 may be configured to control the degree to which lateral current spreading occurs between the bottom of the ridge mesa (stage 4 of FIG. 2A) and the active region 214.

An etch stop layer 226 is grown on the first spacer layer 224. The etch stop layer 226 is provided for stopping the mesa etch performed during stage 4 of FIG. 2A.

A second spacer layer 228 is grown on the etch stop layer 226 to separate the etch stop layer 226 from a grating layer 230.

The grating layer 230 is grown on the second spacer layer 228. The grating layer 230 is “above active” in the illustrated example of FIG. 2B (as compared to other possible designs in which the grating layer is below or integral with the active region 214). In other embodiments, the grating layer 230 can be integrally formed with the active region 214 or below the active region 214. One or more processes, as explained further below, are used to create a uniform grating in the grating layer 230.

A top layer 232 is grown on the grating layer 230 on which re-growth of other layers (e.g., in stage 3 of FIG. 2A) is performed.

2. Stage 2: Grating Etch

Returning to FIG. 2A, after formation of the base epitaxial portion 202 during stage 1, a periodic grating 234 is formed in the grating layer 230 during the second stage. The periodic grating 234 is formed in some embodiments by creating periodic gaps within the grating layer 230 and can be accomplished using any one or more of a variety of techniques, including, for example, photolithography, dry or wet etching, e-beam lithography, holographic lithography, or other suitable technique(s). In other embodiments, the periodic grating 234 is formed in the grating layer 230 in situ by periodically modifying the index of refraction of the grating layer 230 via patterned exposure of the grating layer 230 to light of a particular wavelength, chemical agents, or the like. Other techniques for forming the periodic grating 234 can alternately or additionally be employed.

3. Stage 3: Re-growth

After the periodic grating 234 is formed in grating layer 230 during stage 2 illustrated in FIG. 2A, a first re-growth layer 236 is grown during stage 3 illustrated in FIG. 2A on the periodic grating 234. The first re-growth layer 236 includes InP in some embodiments.

As mentioned above, the periodic grating 234 can be formed by creating periodic gaps within the grating layer 230. Accordingly, the first re-growth layer 236, which typically has an index of refraction that is different than an index of refraction of the grating layer 230, fills in the periodic gaps formed in the grating layer 230.

The periodic grating 234 and the portions of the first re-growth layer 236 that fill in the periodic gaps in the grating layer 230 collectively form a grating, generally designated at 237 in stage 3 of FIG. 2A. The grating 237 has a grating coupling coefficient, κ, that is indicative of the strength of the diffraction grating. The grating coupling coefficient κ depends on, among other things, a thickness T (stage 4 of FIG. 2A) of the grating 237, defined in this and other embodiments as the vertical distance from trough to peak of the periodic grating 234. In some embodiments, the thickness T of the grating 237 is substantially equal to 37 nm. Alternately or additionally, the thickness T of grating 237 is between 30 nm and 40 nm, or even less than 30 nm or more than 40 nm.

Although not shown, a second re-growth layer including Indium Gallium Arsenide (“InGA”), for example, can be grown on the first re-growth layer 236 as an electrical contact.

In some embodiments, the period of the periodic grating 234 and the effective index of the active region 214 are designed to provide the most optical feedback for light having a lasing peak wavelength at room temperature of about 1310 nm. As mentioned above, however, the active region 214 can be designed to produce a gain peak wavelength of about 1340 nm. The setting of the lasing wavelength to a different value than the gain peak wavelength is referred to as “detuning.” In particular, setting the lasing wavelength to a shorter wavelength than the gain peak wavelength is referred to as “negative detuning.”

Further, the difference between the lasing wavelength and the gain peak wavelength is referred to as “spectral gain offset.” In the present example, the spectral gain offset of the DFB laser 200 is about negative 30 nm with the lasing wavelength set at about 1310 nm and the gain peak wavelength set at about 1340 nm. In other embodiments, however, the DFB laser 200 can be negatively detuned to have a spectral gain offset of as little as negative 50 nm or as much as negative 10 nm by designing the active region 214 and/or the period of the periodic grating 234 and the effective index of the active region 214 accordingly.

4. Stage 4: Mesa Etch

With continuing reference to FIG. 2A, the first re-growth layer 236 is used in some embodiments in the formation of a mesa or ridge waveguide 238 on the base epitaxial portion 202. As such, the DFB laser 200 is a ridge waveguide (“RWG”) DFB laser 200.

The mesa 238 can be formed in the first re-growth layer 236 using any one or more of a variety of techniques, including photolithography, dry or wet etching, e-beam lithography, holographic lithography, or other suitable technique(s). The mesa 238 provides current confinement in the DFB laser 200 and also functions as a waveguide by providing lateral optical confinement.

After formation of the mesa 238, a dielectric layer (not shown) is placed on the mesa 238. In some examples, a triple stack of Silicon Nitride, Silicon Dioxide, and Silicon Nitride is used as the dielectric, although more, fewer, and/or other dielectrics may alternately or additionally be used. The dielectric layer confines electric current within the mesa 238. The dielectric layer is removed from the top of the mesa 238 to allow an electrical contact (not shown) and metallic layer (not shown) to be placed on the mesa 238.

The electrical contact is made in some embodiments by depositing metal onto the InGA second re-growth layer (not shown) at the top of the mesa 238. This contact is both a non-alloy contact and a low penetration contact in some examples.

A metallic layer (not shown) is placed on the electrical contact through which electrical current may be provided to the laser structure. In the present embodiment, the metallic layer is made of three sub-layers of titanium, platinum and gold, although other materials could be used. A titanium layer is placed directly on the electrical contact layer, then a platinum layer and a gold layer is applied. This metallic layer provides sufficient conductivity to the InGA second re-growth layer (not shown) so that current can be properly provided to the laser structure. Bottom electrical contacts are generated by thinning the n-InP substrate 204 (FIG. 2B) and placing an n-type metallic layer on the bottom of the n-InP substrate 204.

The process described above with respect to FIGS. 2A and 2B may be employed to produce a wafer from which multiple DFB lasers can be derived. Individual DFB lasers 200 can then be removed from the wafer using common techniques such as cleaving and breaking the wafer both horizontally and laterally to separate each DFB laser 200. In some embodiments, the cleaving locations of the wafer are selected so as to produce DFB lasers 200 having active regions 214 with a length, L (stage 4 of FIG. 2A), substantially equal to 150 μm. Alternately or additionally, the cleaving locations of the wafer are selected so as to produce DFB lasers 200 having active regions 214 with a length L between 120 μm and 180 μm, or even with a length L less than 120 μm or more than 180 μm.

Optionally, one or more antireflective (“AR”) and/or high-reflector (“HR”) coatings can be applied to the cleaved facets of the active region 214 (FIG. 2B) to provide requisite reflectivity characteristics of the DFB laser 200, identified in FIG. 2C as reflectivities R1 and R2. The reflectivity characteristics define the optical power emitted from the back of the DFB laser 200 and the front of the DFB laser 200. In uniform grating designs, a majority of the optical power is emitted from the front of the DFB laser 200 which couples into optical fiber. A minority of the optical power is emitted from the back of the DFB laser 200 which may couple with a monitor photodetector (not shown) that is used to monitor the DFB laser 200 performance.

In some embodiments, the AR and/or HR coatings are made of layers of Silicon Oxide and Silicon. The reflectivity of the AR coating is designed to be less that 5% and the reflectivity of the HR coating is designed to be greater than 94% in some examples. Once the AR/HR coating process is complete, a testing process may be performed in which the power characteristics and optical spectrum of the DFB lasers 200 are tested.

The example DFB laser 200 and optionally a monitor photodetector can be packaged into an optical sub-assembly, which is subsequently packaged into an optoelectronic device, such as the optoelectronic device 100 of FIG. 1, along with, e.g., modulation driver 106, 108, 110, 112 and microcontroller 146 ICs.

Although the above description was specifically tailored to a DFB laser, the examples disclosed herein may also be used in other high-speed lasers, such as 25 G and higher data rate distributed Bragg reflector (“DBR”) lasers. In particular, DBR lasers can also be grown on a substrate with various layers, an active region, a mesa, and so on.

### C. Optimized Laser Structure Design

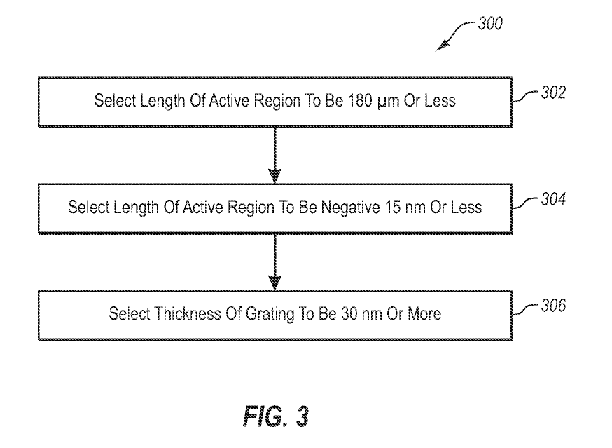

According to some embodiments, the design of the DFB laser 200 is optimized for performance at data rates substantially equal to 25 G. In this and other examples, the optimization varies several parameters, including the volume of the active region 214, the differential gain of the DFB laser 200, and the grating coupling coefficient κ of the grating 237. A method 300 of at least partially optimizing the performance of the DFB laser 200 will now be described with additional reference to FIG. 3.

In some embodiments, the volume of the active region 214 is varied by selecting 302 the length L of the active region 214 to be 180 μm or less, or otherwise reducing the volume of the active region 214 as much as possible. In this and other embodiments, reductions in the active region 214 volume increase the speed (e.g., modulation efficiency) of the DFB laser 200, but also increase the resistance of the DFB laser 200. Assuming no other parameters of the DFB laser 200 are varied, the increased resistance causes an increase in the thermal energy (e.g., heat) generated during operation of the DFB laser 200, thereby reducing absolute gain of the DFB laser 200. Thus, in some embodiments, the volume of the active region 214 is reduced to a point where the benefit of a subsequent increase in speed due to a reduction in active region 214 volume is substantially mitigated by a corresponding degradation in performance caused by the increased resistance of the DFB laser 200. Accordingly, the length L of the active region 214 is selected 302 to be not less than 120 μm in some embodiments. Alternately or additionally, the length L of the active region 214 is selected 302 to be substantially equal to 150 μm.

The differential gain of DFB laser 200 can be varied by detuning the DFB laser 200 to a particular spectral gain offset, as described above with reference to FIG. 2A. More particularly, the differential gain of DFB laser 200 can be increased by negatively detuning the DFB laser 200. In some embodiments, the differential gain is increased by selecting 304 the spectral gain offset of the DFB laser 200 to be negative 10 nm or less. In this and other embodiments, increases in differential gain increase the speed of the DFB laser 200, but also reduce the absolute gain, and therefore increase the threshold current, of the DFB laser 200. In particular, the greater the difference between the lasing peak wavelength of the grating 237 and the gain peak wavelength of the active region 214, the smaller the absolute gain of the DFB laser 200, thereby requiring a greater threshold current to lase. Accordingly, the spectral gain offset of the DFB laser 200 is selected 304 to be not less than negative 50 nm in some embodiments. Alternately or additionally, the spectral gain offset of the DFB laser 200 is selected 304 to be substantially equal to negative 30 nm.

The grating coupling coefficient κ can be varied by selecting 306 the thickness T of the grating 237 to be 30 nm or more, or otherwise strengthening the grating 237 as much as possible while still allowing sufficient output power to be obtained for the DFB laser 200. In this and other embodiments, increasing the strength of the grating 237 increases the absolute gain of the DFB laser 200. As such, the strength of the grating 237 can be increased to mitigate the losses in absolute gain caused by reducing the active region 214 volume and/or increasing the differential gain of the DFB laser 200. However, increasing the strength of the grating 237 also reduces the loss, and hence the optical output power, of the DFB laser 200. Accordingly, the thickness T of the grating 237 is selected 306 to be not more than 40 nm in some embodiments. Alternately or additionally, the thickness T of the grating 237 is selected 306 to be substantially equal to 37 nm.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A distributed feedback laser comprising:
a substrate;
an active region formed above the substrate and designed to emit light having a gain peak wavelength; and
a grating formed above the active region and designed to provide optical feedback for light having a lasing peak wavelength;
wherein the gain peak wavelength is longer than the lasing peak wavelength and a difference between the gain peak wavelength and the lasing peak wavelength at room temperature is between 10 nanometers and 50 nanometers.

2. The distributed feedback laser of claim 1, wherein the distributed feedback laser is configured to operate at a data rate substantially equal to 25 gigabits per second.

3. The distributed feedback laser of claim 1, wherein the difference between the gain peak wavelength and the lasing peak wavelength at room temperature is substantially equal to 30 nanometers.

4. The distributed feedback laser of claim 1, wherein the active region has a length between 120 micrometers and 180 micrometers.

5. The distributed feedback laser of claim 4, wherein the active region has a length substantially equal to 150 micrometers.

6. The distributed feedback laser of claim 1, wherein the grating has a thickness between 30 nanometers and 40 nanometers.

7. The distributed feedback laser of claim 6, wherein the grating has a thickness substantially equal to 37 nanometers.

8. The distributed feedback laser of claim 1, further comprising:
a mode modifier layer grown on the substrate;
a buffer layer grown on the mode modifier layer;
a first n-confinement layer grown on the buffer layer;
a second n-confinement layer grown on the first n-confinement layer;
a first p-confinement layer grown on the active region;
a second p-confinement layer grown on the first p-confinement layer;
a first spacer layer grown on the second p-confinement layer;
an etch stop layer grown on the first spacer layer;
a second spacer layer grown on the etch stop layer;
a grating layer grown on the second spacer layer and having a periodic grating formed therein;
a first re-growth layer grown on the periodic grating and the top layer, wherein a mesa is formed in the first re-growth layer;
a first electrical contact formed above the first re-growth layer; and
a second electrical contact formed below the substrate.

9. The distributed feedback laser of claim 1, wherein:
the substrate comprises n-type Indium Phosphide;
the active region comprises a plurality of quantum wells and a plurality of quantum barriers formed between the plurality of quantum wells; and
the grating comprises an Indium Gallium Arsenide Phosphide grating layer with periodic gaps formed therein, the periodic gaps being filled with an Indium Phosphide re-growth layer.

10. A method of at least partially optimizing output performance of a laser, the method comprising:
selecting a length of an active region of a laser to be 180 micrometers or less;
selecting a spectral gain offset of the laser to be negative 10 nanometers or less; and
selecting a thickness of a grating of the laser to be 30 nanometers or more.

11. The method of claim 10, wherein the selected length of the active region is substantially equal to 150 micrometers.

12. The method of claim 10, wherein the selected length of the active region is not less than 120 micrometers.

13. The method of claim 10, wherein the selected spectral gain offset of the laser is substantially equal to negative 30 nanometers.

14. The method of claim 10, wherein the selected spectral gain offset is not less than negative 50 nanometers.

15. The method of claim 10, wherein the selected thickness of the diffraction grating is substantially equal to 37 nanometers.

16. The method of claim 10, wherein the selected thickness of the diffraction grating is not more than 40 nanometers.

17. An optoelectronic device, comprising:
a driver configured to generate a modulation signal from an electrical data signal received from a host;
an optical transmitter configured for operation at a data rate substantially equal to 25 gigabits per second, the optical transmitter being operably connected to the driver and configured to receive the modulation signal and to emit an optical data signal representative of the electrical data signal, wherein the optical transmitter comprises:
a substrate;
an active region formed above the substrate and designed to emit light having a gain peak wavelength, the active region having a length between 120 micrometers and 180 micrometers; and
a grating formed in the optical transmitter and designed to provide optical feedback for light having a lasing peak wavelength, the grating having a thickness between 30 nanometers and 40 nanometers;
wherein the gain peak wavelength is longer than the lasing peak wavelength and a difference between the gain peak wavelength and the lasing peak wavelength at room temperature is between 10 nanometers and 50 nanometers.

18. The optoelectronic device of claim 17, further comprising:
at least four drivers; and
at least four optical transmitters operably connected to the at least four drivers,
such that the optoelectronic device is configured for operation at a data rate substantially equal to 100 gigabits per second.

19. The optoelectronic device of claim 17, wherein the optical transmitter comprises a ridge waveguide distributed feedback laser or a distributed Bragg reflector laser.

20. The optoelectronic device of claim 19, wherein:
the active region has a length substantially equal to 150 micrometers;
the grating has a thickness substantially equal to 37 nanometers; and
the difference between the gain peak wavelength and the lasing peak wavelength at room temperature is substantially equal to 30 nanometers.
